(19) United States
(12) Patent Application Publication
(10) Pub. No.: US 2015/0255749 A1
(43) Pub. Date: Sep. 10, 2015

(54) GAS PERMEATION BARRIERS AND METHODS OF MAKING THE SAME

(71) Applicant: SAMSUNG SDI CO., LTD., Yongin-si (KR)

(72) Inventors: Xianghui Zeng, Albany, CA (US); Lorenza Moro, Palo Alto, CA (US); Damien Boesch, San Jose, CA (US)

(21) Appl. No.: 14/636,070

(22) Filed: Mar. 2, 2015

Related U.S. Application Data
(60) Provisional application No. 61/950,812, filed on Mar. 10, 2014.

(51) Int. Cl. H01L 51/52; H01L 51/56

(52) U.S. Cl. CPC H01L 51/5256; H01L 51/56

(57) ABSTRACT

Barrier stacks according to embodiments of the present invention achieve good water vapor transmission rates with a reduced number of dyads (i.e., polymer layer/oxide layer couple). In some embodiments, the barrier stack includes one or more dyads comprising a first polymer decoupling layer and a second barrier layer on the first layer. An intervening tie layer is deposited between the first and second layers of at least one of the dyads. The intervening tie layer includes an inorganic oxide layer deposited between the polymer decoupling layer and barrier layer of the dyad. The barrier layer includes a silicon nitride layer deposited by an evaporative deposition technique such as chemical vapor deposition (CVD), for example plasma enhanced chemical vapor deposition (PECVD). The barrier stack including the intervening tie layer has a water vapor transmission rate that is lower than a water vapor transmission rate of a barrier stack not including the intervening tie layer.

### CROSS-REFERENCE TO RELATED APPLICATION(S)

This application claims priority to and the benefit of U.S. Provisional Application Ser. No. 61/950,812 filed on Mar. 10, 2014 and titled A METHOD TO IMPROVE THE ADHESION AND PERFORMANCE OF GAS PERMEATION BARRIERS ON SUBSTRATES, the entire content of which is incorporated herein by reference.

### BACKGROUND

Many devices, such as organic light emitting devices and the like, are susceptible to degradation from the permeation of certain liquids and gases, such as water vapor and oxygen present in the environment, and other chemicals that may be used during the manufacture, handling or storage of the product. To reduce permeability to these damaging liquids, gases and chemicals, the devices are typically coated with a barrier coating or are encapsulated by incorporating a barrier stack adjacent one or both sides of the device.

Barrier coatings typically include a single layer of inorganic material, such as aluminum, silicon or aluminum oxides, or silicon nitrides. However, for many devices, a single layer barrier coating does not sufficiently reduce or prevent oxygen or water vapor permeability. Indeed, in organic light emitting devices, for example, which require exceedingly low oxygen and water vapor transmission rates, single layer barrier coatings do not adequately reduce or prevent the permeability of damaging gases, liquids and chemicals. Accordingly, in those devices (e.g., organic light emitting devices and the like), barrier stacks have been used in an effort to further reduce or prevent the permeation of damaging gases, liquids and chemicals.

In general, a barrier stack includes multiple dyads, each dyad being a two-layered structure including a barrier layer and a decoupling layer. The barrier stack can be deposited directly on the device to be protected, or may be deposited on a separate film or support, and then laminated onto the device. The decoupling layer(s) and barrier layer(s) can be deposited by any of various techniques (e.g., vacuum deposition processes or atmospheric processes), but the deposition of suitably dense layers with appropriate barrier properties is typically achieved by supplying energy to the material that will ultimately form the layer. The energy supplied to the material can be thermal energy, but in many deposition processes, ionization radiation is used to increase the ion production in the plasma and/or to increase the number of ions in the evaporated material streams. The produced ions are then accelerated toward the substrate either by applying a DC or AC bias to the substrate, or by building up a potential difference between the plasma and the substrate.

For example, low energy plasma can be used to deposit the oxides of a barrier layer. However, a layer deposited using such low energy plasma has surface defects and low density, providing limited protection of the encapsulated device (e.g., an organic light emitting device) from the permeation of damaging gases, liquids, and chemicals. A common solution to these problems has been to provide multiple dyads (i.e., multiple stacks of the decoupling and barrier layers) in order to provide an effective barrier stack (or ultrabarrier). However, such a practice increases the cost and time of manufacture.

On the other hand, while higher energy plasma can be used to make higher quality barrier films, such high energy plasma can damage the underlying polymer decoupling layer. Additionally, some substrates (e.g., certain plastic substrates) cannot withstand the high energy and/or high temperatures of such a deposition process. As an alternative to these sputtering techniques, some barrier materials can be deposited by other, less damaging processes. For example, certain material may be deposited by chemical vapor deposition techniques, which require lower temperatures, thereby reducing damage to the underlying polymer decoupling layer and/or substrate. However, these processes typically do not create barrier layers with sufficient barrier properties (e.g., water vapor and oxygen transmission rates) to effectively protect the underlying device. Accordingly, barrier layers deposited by these processes also require multiple dyads in order to provide an effective barrier stack (or ultrabarrier). However, as noted above, such a practice increases the cost and time of manufacture.

### SUMMARY

According to embodiments of the present invention, a barrier stack includes one or more dyads, where each dyad includes a first layer including a polymer or organic material, and a second layer including a silicon nitride barrier material. The barrier stack also includes an intervening tie layer including an inorganic oxide between the first layer and the second layer of one or more of the one or more dyads. The barrier stack including the intervening tie layer may have a water vapor transmission rate that is lower than a water vapor transmission rate of a barrier stack including the one or more dyads but not including the intervening tie layer.

In some embodiments, the barrier stack may further include a fourth layer, where the first layer is on the fourth layer.

In some embodiments, the polymer or organic material is selected from organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

In some embodiments, the silicon nitride barrier material includes Si₃N₄.

In some embodiments, the inorganic oxide includes an oxide of Al, Zr, Ti, Si, and combinations thereof. For example, the inorganic oxide includes Al₂O₃ and/or SiO₂.

In some embodiments, the intervening tie layer has a thickness of 25 nm or less, for example 20 nm or less. In some embodiments, for example, the intervening tie layer has a thickness of 10 nm to 25 nm.

According to some embodiments, a method of making a barrier stack includes forming one or more dyads, where forming each of the dyads comprises forming a first layer comprising a polymer or organic material, and forming a second layer comprising a silicon nitride barrier material. The method further includes depositing an intervening tie layer including an inorganic oxide between the first layer and the second layer of one or more of the one or more dyads. The barrier stack including the intervening tie layer may have a water vapor transmission rate that is lower than a water vapor transmission rate of a barrier stack comprising the one or more dyads but not including the intervening tie layer.

The method may further include forming the first layer on a fourth layer.

In some embodiments, the intervening tie layer is deposited to a thickness of 25 nm or less.

In some embodiments, a barrier stack includes no more than 2 dyads, where each dyad includes a first layer including a polymer or organic material, and a second layer including a silicon nitride barrier material. The barrier stack further includes an intervening tie layer including an inorganic oxide between the first layer and the second layer of one or more of the no more than 2 dyads. The barrier stack has a water vapor transmission rate on the order of 10⁻⁴ g/m²·day or better.

In some embodiments, the no more than 2 dyads includes no more than one dyad.

In some embodiments, the intervening tie layer has a thickness of 25 nm or less.

### BRIEF DESCRIPTION OF THE DRAWINGS

These and other features and advantages of the present invention will be better understood by reference to the following detailed description when considered in conjunction with the following drawings, in which:

FIG. 1 is a schematic view of a barrier stack according to an embodiment of the present invention;

FIG. 2 is a schematic view of a barrier stack according to another embodiment of the present invention; and

FIG. 3 is a schematic view of a barrier stack according to yet another embodiment of the present invention.

### DETAILED DESCRIPTION

In embodiments of the present invention, a barrier stack includes a silicon nitride barrier layer on an intervening, adhesion promoting tie layer (also referred to herein as simply an “intervening tie layer”). The adhesion promoting, intervening tie layer enables the reduction in the number of dyads needed to produce an “ultrabarrier” that is effective in protecting the underlying (or encapsulated) device from the permeation of moisture and oxygen, among other harmful elements. The intervening, adhesion promoting tie layer is deposited between the decoupling layer of dyad and the silicon nitride barrier layer, and promotes and improves adhesion of the silicon nitride barrier layer to the underlying polymer decoupling layer. The increased adhesion of the silicon nitride barrier layer to the underlying decoupling layer results in a barrier stack having improved water vapor transmission properties, and fewer dyads are needed to provide a target water vapor transmission rate.

In some embodiments of the present invention, a barrier stack includes at least one dyad, and an intervening, adhesion promoting tie layer between the layers of the dyad. Each of the dyads includes a first layer that acts as a smoothing or planarization layer, and a second layer that acts as a barrier layer. The intervening, adhesion promoting tie layer is deposited between the first layer (i.e., the decoupling layer or smoothing or planarization layer) and the second layer (i.e., the barrier layer, which includes a silicon nitride or similar material). The layers of the barrier stack can be directly deposited on a device to be encapsulated (or protected) by the barrier stack, or may be deposited on a separate substrate or support, and then laminated on the device.

The first layer of the dyad includes a polymer or other organic material that serves as a planarization, decoupling and/or smoothing layer. Specifically, the first layer decreases surface roughness, and encapsulates surface defects, such as pits, scratches, digs and particles, thereby creating a planarized surface that is ideal for the subsequent deposition of additional layers. As used herein, the terms “first layer,” “smoothing layer,” “decoupling layer,” and “planarization layer” are used interchangeably, and all terms refer to the first layer, as now defined. The first layer can be deposited directly on the device to be encapsulated (e.g., an organic light emitting device), or may be deposited on a separate support. The first layer may be deposited on the device or substrate by any suitable deposition technique, some nonlimiting examples of which include vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The first layer can include any suitable material capable of acting as a planarization, decoupling and/or smoothing layer. Some nonlimiting examples of suitable such materials include organic polymers, inorganic polymers, organometallic polymers, hybrid organic/inorganic polymer systems, and silicates. In some embodiments, for example, the material of the first layer may be an acrylate-containing polymer, an alkylacrylate-containing polymer (including but not limited to methacrylate-containing polymers), or a silicon-based polymer.

The first layer can have any suitable thickness such that the layer has a substantially planar and/or smooth layer surface. As used herein, the term “substantially” is used as a term of approximation and not as a term of degree, and is intended to account for normal variations and deviations in the measurement or assessment of the planar or smooth characteristic of the first layer. In some embodiments, for example, the first layer has a thickness of about 100 to 1000 nm.

The second layer of the dyad is the layer that operates as the barrier layer, preventing the permeation of damaging gases, liquids and chemicals to the encapsulated device. Indeed, as used herein, the terms “second layer” and “barrier layer” or “silicon nitride barrier layer” are used interchangeably. The second layer includes a silicon nitride that is deposited on the first layer by an evaporative deposition technique. For example, the silicon nitride of the second layer may be deposited by chemical vapor deposition (CVD), e.g., plasma enhanced chemical vapor deposition (PECVD). The conditions of evaporative deposition (e.g., CVD or PECVD) are not particularly limited. In some embodiments, however, the deposition process includes the plasma enhanced chemical vapor deposition of the silicon nitride film using of silane (SiH₄) and ammonia (NH₃) source gases Indeed, the deposition of silicon nitride and similar materials using these deposition techniques is well known in the art, and those of ordinary skill in the art would be readily capable of selecting suitable conditions and deposition parameters to deposit a silicon nitride (or similar material) film with the thickness described in this application.

The silicon nitride material of the second layer is not particularly limited, and may be any silicon nitride suitable for substantially preventing or reducing the permeation of damaging gases, liquids and chemicals (e.g., oxygen and water vapor) to the encapsulated device. In some embodiments, however, the silicon nitride material (SiNₓ) may be Si₃N₄.

The thickness of the silicon nitride barrier film (i.e., the second layer) is not particularly limited. However, the thickness of the second layer is greater than the thickness of the intervening, adhesion promoting tie layer. For example, in some embodiments, a ratio of the thickness of the intervening tie layer to the thickness of second layer is 1:5 to 1:10. In some embodiments, the silicon nitride barrier film (i.e., the second layer) may have a thickness of 20 nm to 150 nm, for example 40 nm to 100 nm, or 60 nm to 100 nm. In some embodiments, for example, the thickness of the second layer may be 100 nm.

According to embodiments of the present invention, the barrier stack includes an intervening, adhesion promoting tie layer that includes a metal oxide material, and serves as an adhesion promoting layer, improving adhesion between the silicon nitride barrier layer (i.e., the second layer) and the decoupling layer (i.e., the first layer). To improve adhesion between the first and second layers, the intervening tie layer is deposited between the first layer and the second layer to a thickness suitable for promoting adhesion but that does not enable the intervening tie layer to contribute substantially to the barrier property of the barrier stack. As used herein, the term “substantially” is used as a term of approximation and not as a term of degree, and is intended to account for normal variations and deviations in the measurement or assessment of a contribution to the barrier properties of the stack. In some embodiments, for example, the intervening tie layer has a thickness of less than 25 nm, for example less than 20 nm. For example, in some embodiments, the intervening tie layer has a thickness of 5 nm to 25 nm, for example 10 nm to 25 nm. In some embodiments, for example, the intervening tie layer has a thickness of 5 nm to 20 nm, for example 10 nm to 20 nm. For example, in some embodiments, the intervening tie layer has a thickness of 10 nm.

As discussed above, the intervening tie layer is deposited on the first layer, and the second layer is deposited on the intervening tie layer. Deposition of the intervening tie layer may vary depending on the material used for the intervening tie layer. However, in general, any deposition technique and any deposition conditions can be used to deposit the intervening tie layer. For example, the intervening tie layer may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof.

In some embodiments, however, the intervening tie layer is deposited by AC or DC sputtering. For example, in some embodiments, the intervening tie layer is deposited by AC sputtering. The AC sputtering deposition technique offers the advantages of faster deposition, process stability, control, fewer particles and fewer arcs. The conditions of the AC sputtering deposition are not particularly limited, and as would be understood by those of ordinary skill in the art, the conditions will vary depending on the area of the target and the distance between the target and the substrate. In some exemplary embodiments, however, the AC sputtering conditions may include a power of about 3 to about 6 kW, for example about 4 kW, a pressure of about 2 to about 6 mTorr, for example about 4.4 mTorr, an Ar flow rate of about 80 to about 120 sccm, for example about 100 sccm, a target voltage of about 350 to about 550 V, for example about 480V, and a track speed of about 90 to about 200 cm·min, for example about 141 cm/min. Also, although the inert gas used in the AC sputtering process can be any suitable inert gas (such as helium, xenon, krypton, etc.), in some embodiments, the inert gas is argon (Ar).

The material of the intervening tie layer is not particularly limited, and may be any inorganic oxide material suitable for promoting adhesion of the silicon nitride barrier layer (i.e., the second layer) to the polymer decoupling layer (i.e., the first layer). Some nonlimiting examples of suitable materials for the intervening tie layer include metal oxides, for example metal oxides of metals including Al, Zr, Si or Ti. In some embodiments, for examples the tie layer includes aluminum or silicon oxide (e.g., Al₂O₃ or SiO₂).

In some embodiments, the intervening tie layer is deposited between the first and second layers of only one of the dyads of the barrier stack. For example, in some embodiments, the intervening tie layer may be deposited between the first and second layers of only the outermost dyad (i.e., the dyad furthest from the substrate or encapsulated device). In some embodiments, for example, the intervening tie layer may be deposited between the first and second layers of only the innermost dyad (i.e., the dyad closest to the substrate or encapsulated device). For example, in some embodiments, an intervening tie layer may be deposited between the first and second layers of both the innermost and outermost dyad. In some embodiments, an intervening tie layer may be deposited between the first and second layers of each of the dyads in the barrier stack. In some embodiments, for example, the barrier stack includes only one dyad, and therefore only one intervening tie layer between the first and second layers of the only dyad. Indeed, as the intervening tie layer improves adhesion between the first and second layers of the dyad, and therefore improves the overall barrier performance of the barrier stack, in some embodiments, the barrier stack includes a reduced number of dyads, e.g., 2 or fewer dyads, for example 1 dyad. Even though the barrier stacks according to such embodiments include fewer dyads, they achieve improved barrier properties, such as water vapor transmission rate.

In particular, in some embodiments, the barrier stack without the intervening tie layer registers a water vapor transmission rate that is measurably greater than the water vapor transmission rate of the same barrier stack including the intervening tie layer. For example, in some embodiments, the inclusion of the intervening tie layer according to embodiments of the present invention can improve the water vapor transmission rate of the barrier stack by up to a full order of magnitude, and in some embodiments, by 1 to 3 full orders of magnitude, for example 2 to 3 full orders of magnitude, or 2 full orders of magnitude. Specifically, in some embodiments, the barrier stack without the intervening tie layer may have a water vapor transmission rate on the order of 10⁻¹ g/m²·day to 10⁻³ g/m²·day, and the barrier stack with the intervening tie layer may have a water vapor transmission rate of 10⁻⁴ g/m²·day to 10⁻⁵ g/m²·day.

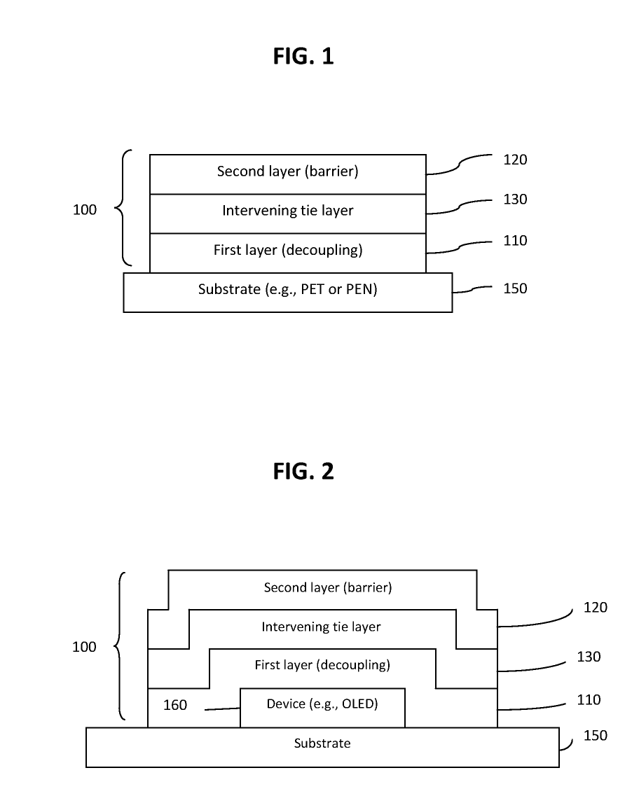

Exemplary embodiments of a barrier stack according to the present invention are illustrated in FIGS. 1 and 2. The barrier stack 100 depicted in FIG. 1 includes a first layer 110 which includes a decoupling layer or smoothing layer (i.e., the first layer discussed above), a second layer 120 which includes a barrier layer (i.e., the second layer discussed above), and intervening tie layer 130. In FIG. 1, the barrier stack 100 is deposited on a substrate 150, for example glass or plastic (such as, for example, polyethylene naphthalate (PEN) or polyethylene terephthalate (PET)). However, in FIG. 2, the barrier stack 100 is deposited directly on the device 160, e.g., an organic light emitting device.

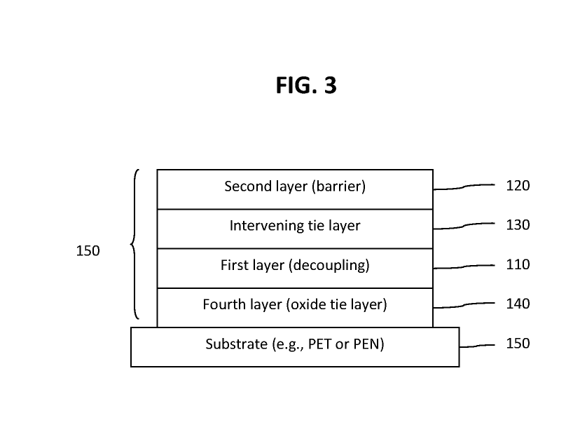

In addition to the first and second layers 110 and 120, respectively, making up a dyad, and the intervening tie layer 130, some exemplary embodiments of the barrier stack 100 can include a fourth layer 140 between the first layer 110 and the substrate 150 or the device 160 to be encapsulated. Although the inventive barrier stacks are discussed herein and depicted in the accompanying drawings as including first and second layers 110 and 120, respectively, of a dyad, an intervening tie layer 130, and a fourth layer 140, it is understood that these layers may be deposited on the substrate 150 or the device 160 in any order so long as the intervening tie layer 130 is between the first and second layers of at least one of the dyads, and the identification of the first, second and fourth layers as first, second, and fourth, respectively, does not mean that these layers must be deposited in that order. Indeed, as discussed here, and depicted in FIG. 3, in some embodiments, the fourth layer 140 is deposited on the substrate 150 or device 140 prior to deposition of the first layer 110.

The fourth layer 140 acts as a substrate tie layer, improving adhesion between the layers of the barrier stack 100 and the substrate 150 or the device 160 to be encapsulated. In particular, the fourth layer 140 is typically the first layer deposited on the substrate, prior to deposition of the first layer 110 (i.e., the polymer decoupling layer), and acts to improve adhesion of the first layer to the substrate or device for encapsulation. The material of the fourth layer 140 is not particularly limited, and can include the materials described above with respect to the intervening tie layer 130. Also, the material of the fourth layer may be the same as or different from the material of the intervening tie layer 130. The materials of the intervening tie layer 130 are described in detail above.

Additionally, the fourth layer may be deposited on the substrate or the device to be encapsulated by any suitable technique, including, but not limited to the techniques described above with respect to the intervening tie layer. In some embodiments, for example, the fourth layer may be deposited by AC or DC sputtering under conditions similar to those described above for the intervening tie layer. Also, the thickness of the deposited fourth layer is not particularly limited, and can be any thickness suitable to effect good adhesion between the first layer of the barrier stack and the substrate or device to be encapsulated. In some embodiments, for example, the fourth (substrate tie) layer can have a thickness of about 20 nm to about 60 nm, for example, about 40 nm.

An exemplary embodiment of a barrier stack 100 according to the present invention including a fourth layer 140 is depicted in FIG. 3. The barrier stack 100 depicted in FIG. 3 includes a first layer 110 which includes a decoupling layer, a fourth layer 140 which includes a substrate tie layer, a second layer 120 which includes a barrier layer, and an intervening tie layer 130 which is between the first layer 110 and the second layer 120. In FIG. 3, the barrier stack 100 is deposited on a substrate 150, for example glass or plastic (e.g., PET or PEN). However, it is understood that the barrier stack 100 can alternatively be deposited directly on the device 160, e.g., an organic light emitting device, as depicted in FIG. 2 with respect to the embodiments excluding the fourth layer.

In some embodiments of the present invention, a method of making a barrier stack includes providing a substrate 150, which may be a separate substrate support or may be a device 160 for encapsulation by the barrier stack 100 (e.g., an organic light emitting device or the like). The method further includes forming a first layer 110 on the substrate. The first layer 110 is as described above and acts as a decoupling/smoothing/planarization layer. As also discussed above, the first layer 110 may be deposited on the device 160 or substrate 150 by any suitable deposition technique, including, but not limited to, vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The method further includes depositing an intervening tie layer 130 on the first layer 110. The intervening tie layer 130 is as described above and acts as an adhesion promoting layer, serving to promote or improve adhesion of the subsequently deposited second layer 120 to the first layer 110. The deposition of the intervening tie layer 130 may vary depending on the material used for the intervening tie layer. However, in general, any deposition technique and any deposition conditions can be used to deposit the intervening tie layer. For example, the intervening tie layer 130 may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof. In some embodiments, however, the intervening tie layer 130 is deposited by AC or DC sputtering, for example pulsed AC or pulsed DC sputtering. While any suitable conditions for deposition can be employed, some suitable conditions are described above.

As discussed above, the intervening tie layer improves adhesion between the first and second layers, and is deposited between the first layer and the second layer to a thickness suitable for promoting adhesion but that does not enable the intervening tie layer to contribute substantially to the barrier property of the barrier stack. In some embodiments, for example, the intervening tie layer has a thickness of less than 25 nm, for example less than 20 nm. For example, in some embodiments, the intervening tie layer has a thickness of 5 nm to 25 nm, for example 10 nm to 25 nm. In some embodiments, for example, the intervening tie layer has a thickness of 5 nm to 20 nm, for example 10 nm to 20 nm. For example, in some embodiments, the intervening tie layer has a thickness of 10 nm.

Additionally, the method includes depositing a second layer 120 on the intervening tie layer 130. The second layer 120 is as described above and acts as the barrier layer of the barrier stack, serving to substantially prevent or substantially reduce the permeation of damaging gases, liquids and chemicals to the underlying device. As discussed above, the second layer includes a silicon nitride that is deposited on the first layer by an evaporative deposition technique. For example, the silicon nitride of the second layer may be deposited by chemical vapor deposition (CVD), e.g., plasma enhanced chemical vapor deposition (PECVD). As discussed above, the conditions of evaporative deposition (e.g., CVD or PECVD) are not particularly limited. In some embodiments, however, the deposition process includes the plasma enhanced chemical vapor deposition of the silicon nitride film using silane (SiH₄) and ammonia (NH₃) source gases Indeed, the deposition of silicon nitride and similar materials using these deposition techniques is well known in the art, and those of ordinary skill in the art would be readily capable of selecting suitable conditions and deposition parameters to deposit a silicon nitride (or similar material) film with the thickness described in this application.

According to some embodiments, the method may further include pretreating the intervening tie layer with a suitable plasma or gas prior to depositing the second layer. The material of the pretreatment gas or plasma is not particularly limited. However, in some embodiments, the intervening tie layer may be pretreated with O₂ or NH₃. Some additional nonlimiting examples of suitable gases and/or plasmas for pretreating the intervening tie layer include Ar and N₂. The process of pretreating an underlying substrate prior to evaporative deposition of a silicon nitride is known in the art, and those of ordinary skill in the art would be capable of selecting suitable parameters for this pretreatment.

In some embodiments, the method further includes depositing a fourth layer 140 between the substrate 150 (or the device 160 to be encapsulated) and the first layer 110. The fourth layer 140 is as described above and acts as a substrate tie layer for improving adhesion between the substrate or device and the first layer 110 of the barrier stack 100. The fourth layer 140 may be deposited by any suitable technique, as discussed above. For example, as also discussed above, the fourth layer 140 may be deposited on the substrate 150 (or the device 160 to be encapsulated) by AC or DC sputtering, e.g., pulsed AC or pulsed DC sputtering.

The following Examples are provided for illustrative purposes only, and do not limit the present disclosure.

### Example 1

A barrier stack was prepared by depositing a substrate tie layer and polymeric decoupling layer on a polyethylene naphthalate substrate. An intervening tie layer including a 10 nm thick Al₂O₃ intervening tie layer was deposited by pulsed DC sputtering on the polymeric decoupling layer. Then, a 100 nm thick SiNx barrier layer was deposited by CVD on the intervening tie layer.

The barrier stack according to Example 1 was subjected to nearly 150 hours of accelerated aging in a 40° C. over at 90% relative humidity, and the water vapor transmission rate of the barrier stack was measured using a permeation measuring instrument from Mocon (Minneapolis, Minn.). The barrier stack according to Example 1 registered a water vapor transmission rate of less than 5.0×10⁻⁴ g/m²·day.

### Example 2

A simplified test barrier stack was prepared by depositing a substrate tie layer on a Calcium coupon and depositing a polymeric decoupling layer on the substrate tie layer. Then, a 10 nm thick Al₂O₃ intervening tie layer was deposited by pulsed DC sputtering on the polymeric decoupling layer, and the intervening tie layer was pretreated with O₂ in preparation for deposition of a SiNₓ layer. Finally, a 100 nm thick SiNₓ barrier layer was deposited by CVD on the intervening tie layer.

### Example 3

A simplified test barrier stack was prepared by depositing a substrate tie layer on a Calcium coupon and depositing a polymeric decoupling layer on the substrate tie layer. Then, a 10 nm thick Al₂O₃ intervening tie layer was deposited by pulsed DC sputtering on the polymeric decoupling layer, and the intervening tie layer was pretreated with NH₃ in preparation for deposition of a SiNₓ layer. Finally, a 100 nm thick SiNₓ barrier layer was deposited by CVD on the intervening tie layer.

Each of the simplified barrier stacks according to Examples 2 and 3 were was subjected to 540 hours of accelerated aging in an 85° C. oven at 85% relative humidity. Each of the barrier stacks maintained a satisfactory water vapor transmission rate throughout the 540 hours of accelerated aging.

As discussed above, according to embodiments of the present invention, a barrier stack includes at least one dyad and an intervening, adhesion promoting tie layer between the barrier layer and the decoupling layer of at least one of the dyads. The intervening tie layer increases the reliability of the barrier created by the barrier stack, and enables a reduction in the number of dyads needed to create an effective barrier. For example, where other barrier stacks not including an intervening tie layer may require 3 or more dyads to create a barrier with a sufficient water vapor transmission rate (e.g., a water vapor transmission rate on the order of 10⁻⁴ b/m²·day), barrier stacks including an intervening tie layer according to embodiments of the present invention can achieve the same or better water vapor transmission rate (e.g., a water vapor transmission rate on the order of 10⁻⁴ b/m²·day or better, for example, 10⁻⁵ b/m²·day or better) with fewer than 3 dyads, for example 1 or 2 dyads. For example, in some embodiments, the barrier stack includes no more than 2 dyads. Indeed, in some embodiments, the barrier stack includes only one dyad.

Additionally, the barrier stacks according to embodiments of the present invention achieve improved barrier properties compared to similar barrier stacks not including the intervening tie layer. For example, where similar single dyad silicon nitride barrier stacks not including an intervening tie layer between the first and second layers may achieve a water vapor transmission rate on the order of 10⁻² b/m²·day or at best 10⁻³ b/m²·day, the barrier stacks according to embodiments of the present invention can achieve improved water vapor transmission rates of 10⁻⁴ b/m²·day or better (for example, 10⁻⁵ b/m²·day or better) with a single dyad. The barrier stacks according to embodiments of the present invention can be used for either direct thin film encapsulation of sensitive devices (such as, e.g., OLEDs), or for ultra-barrier laminates deposited on a plastic foil to be used as a substrate or encapsulation by lamination of the sensitive device.

While certain exemplary embodiments of the present invention have been illustrated and described, it is understood by those of ordinary skill in the art that certain modifications and changes can be made to the described embodiments without departing from the spirit and scope of the present invention.

What is claimed is:

1. A barrier stack, comprising:
one or more dyads, each dyad comprising a first layer comprising a polymer or organic material, and a second layer comprising a silicon nitride barrier material;
an intervening tie layer comprising an inorganic oxide between the first layer and the second layer of one or more of the one or more dyads.

2. The barrier stack of claim 1, wherein the barrier stack including the intervening tie layer has a water vapor transmission rate that is lower than a water vapor transmission rate of a barrier stack comprising the one or more dyads but not including the intervening tie layer.

3. The barrier stack of claim 1, further comprising a fourth layer, wherein the first layer is on the fourth layer.

4. The barrier stack of claim 1, wherein the polymer or organic material is selected from the group consisting of organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

5. The barrier stack of claim 1, wherein the silicon nitride barrier material comprises Si₃N₄.

6. The barrier stack of claim 1, wherein the inorganic oxide comprises an oxide of Al, Zr, Ti, Si, and combinations thereof.

7. The barrier stack of claim 1, wherein the inorganic oxide comprises Al₂O₃ and/or SiO₂.

8. The barrier stack of claim 1, wherein the intervening tie layer has a thickness of 25 nm or less.

9. The barrier stack of claim 1, wherein the intervening tie layer has a thickness of 10 nm to 25 nm.

10. A method of making a barrier stack, comprising:
forming one or more dyads, wherein forming each of the dyads comprises forming a first layer comprising a polymer or organic material, and forming a second layer comprising a silicon nitride barrier material; and
depositing an intervening tie layer comprising an inorganic oxide between the first layer and the second layer of one or more of the one or more dyads.

11. The method of claim 10, wherein the barrier stack including the intervening tie layer has a water vapor transmission rate that is lower than a water vapor transmission rate of a barrier stack comprising the one or more dyads but not including the intervening tie layer.

12. The method of claim 10, further comprising forming the first layer on a fourth layer.

13. The method of claim 10, wherein the polymer or organic material is selected from the group consisting of organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

14. The method of claim 10, wherein the silicon nitride barrier material comprises Si₃N₄.

15. The method of claim 10, wherein the inorganic oxide comprises an oxide of Al, Zr, Ti, Si, and combinations thereof.

16. The method of claim 10, wherein the inorganic oxide comprises Al₂O₃ and/or SiO₂.

17. The method of claim 10, wherein the intervening tie layer has a thickness of 25 nm or less.

18. A barrier stack, comprising:
no more than 2 dyads, each dyad comprising a first layer comprising a polymer or organic material, and a second layer comprising a silicon nitride barrier material;
an intervening tie layer comprising an inorganic oxide between the first layer and the second layer of one or more of the no more than 2 dyads, wherein the barrier stack has a water vapor transmission rate on the order of 10⁻⁴ g/m²·day or better.

19. The barrier stack of claim 18, wherein the no more than 2 dyads comprises no more than one dyad.

20. The barrier stack of claim 18, wherein the intervening tie layer has a thickness of 25 nm or less.
